(19) United States
(12) Patent Application Publication
(10) Pub. No.: US 2013/0229765 A1
(43) Pub. Date: Sep. 5, 2013

(54) TEMPERATURE CONTROL DEVICE FOR HARD DISK DRIVE OF SERVER SYSTEM

(71) Applicants: HONG FU JIN PRECISION INDUSTRY (SHENZHEN) CO., LTD., Shenzhen (CN); HON HAI PRECISION INDUSTRY CO., LTD., New Taipei (TW)

(72) Inventors: CHENG-FEI WENG, Shenzhen (CN); JIE LI, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/750,043

(22) Filed: Jan. 25, 2013

(30) Foreign Application Priority Data
Mar. 2, 2012 (CN) 201220074428.7

(51) Int. Cl. G06F 1/20; H05K 7/20

(52) U.S. Cl. CPC G06F 1/206; H05K 7/20209
USPC 361/679.33; 165/247

(57) ABSTRACT

A temperature control device includes a temperature sensing group, a plurality of fans, and a controller. The temperature sensing group includes a plurality of sensing modules, each sensing module detects a temperature of a hard disk drive, numbers the hard disk drive, and outputs the temperature and a number signal corresponding to the hard disk drive. The plurality of fans each faces and corresponding to one or more hard disk drives. The controller is electronically connected to the plurality of sensing modules and the plurality of fans, the controller receives the temperature and number signal from each sensing module, finds a corresponding fan according each number signal, and regulates a rotational speed of the corresponding fan according to the temperature of the hard disk drive.

### BACKGROUND

1. Technical Field

The exemplary disclosure generally server systems, and particularly to a temperature control device for hard disk drives of a server system.

2. Description of Related Art

A 1U server system may include eight hard disk drives sharing a hard disk backboard in a 1U chassis. The sever system further includes a fan device to dissipate heat generated by the hard disk drives. Rotational speed of the whole fan device is increased to speed up the dissipation of heat when temperature of even one or two hard disk drives is increased, which will use more power and increase electricity costs.

Therefore, there is room for improvement within the art.

### BRIEF DESCRIPTION OF THE DRAWINGS

Many aspects of the embodiments can be better understood with reference to the drawings. The components in the drawings are not necessarily drawn to scale, the emphasis instead being placed upon clearly illustrating the principles of the disclosure.

FIG. 1 shows a block diagram of an exemplary embodiment of a server system comprising a temperature control device for hard disk drives.

FIG. 2 shows an exemplary circuit diagram of a temperature sensing group of the temperature control device shown in FIG. 1.

### DETAILED DESCRIPTION

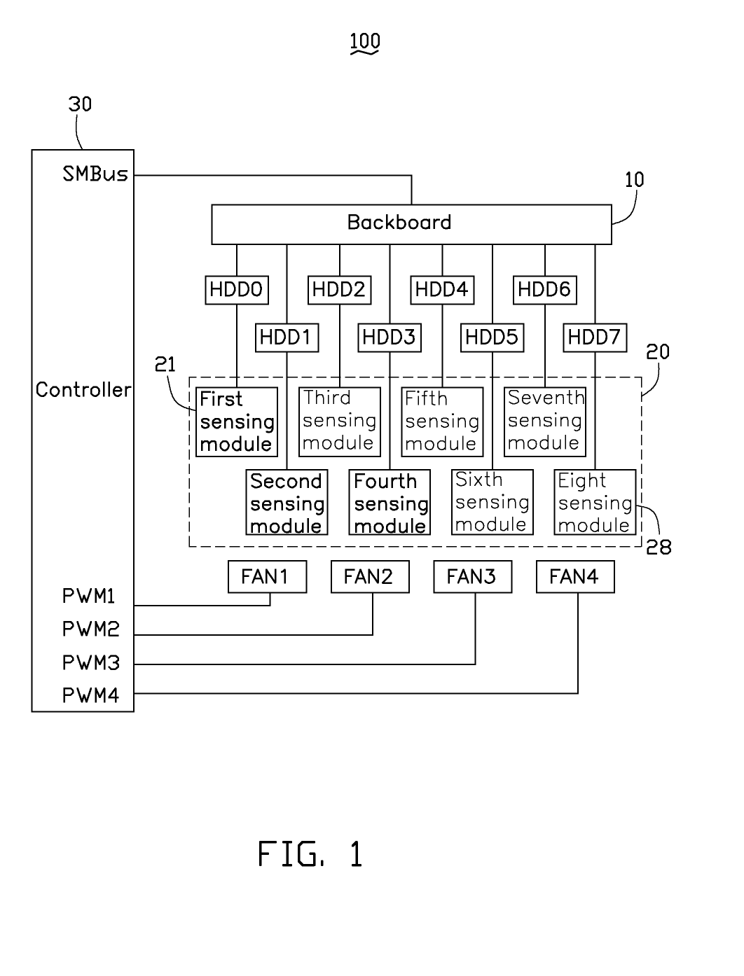

FIG. 1 shows a block diagram of an exemplary embodiment of a server system 100 comprising a temperature control device for hard disk drives. The server system 100 includes a hard disk backboard 10, the temperature control device, and a plurality of hard disk drives electronically connected to the backboard 10. In the exemplary embodiment, the server system 100 includes eight hard disk drives HDD0-HDD7, but the disclosure is not limited thereto. The temperature control device includes a temperature sensing group 20, a fan group, and a controller 30.

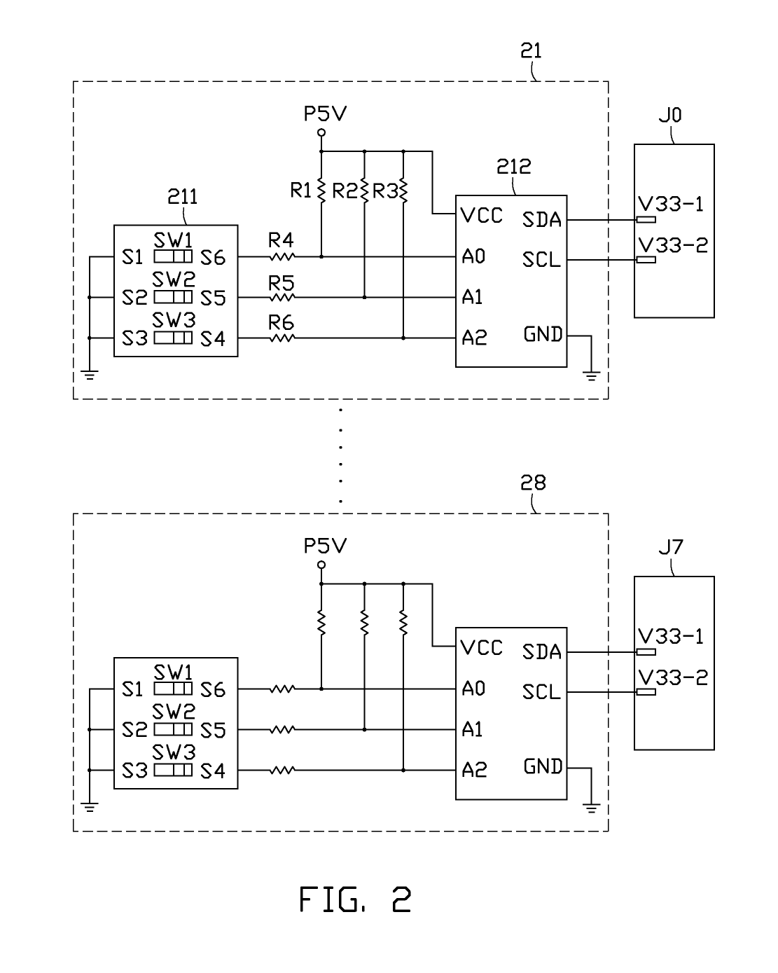

FIG. 2 shows an exemplary circuit diagram of the temperature sensing group 20 of the temperature control device shown in FIG. 1. Each hard disk drive includes a gold finger connecting the hard disk drive to the backboard 10. Since the gold fingers are electronically connected to the backboard 10 in a method well known in the art, the connection circuits between the gold fingers and the backboard 10 are not shown in FIGS. 1 and 2. Each gold finger includes a group of unused power pins. For example, the hard disk drive HDD0 includes a gold finger J0 including a group of unused power pins V33-1 and V33-2; and the hard disk drive HDD7 includes a gold finger J7 including a group of unused power pins V33-1 and V33-2. The temperature sensing group 20 includes eight sensing modules arranged corresponding to the hard disk drives HDD0-HDD7 respectively. The first and the eighth sensing modules are labeled 21 and 28 respectively in FIGS. 1 and 2, and the second to seventh sensing modules are not labeled. Each sensing module is disposed adjacent to the corresponding hard disk drive, to detect temperature of the corresponding hard disk drive. For example, the first sensing module 21 is disposed adjacent to the hard disk drive HDD0, to detect temperature of the hard disk drive HDD0. Each sensing module includes a switch, and a sensor electronically connected to the switch and a gold finger of a corresponding hard disk drive. The sensor detects the temperature of the corresponding hard disk drive, numbers the corresponding hard disk drive in conjunction with the switch, and outputs the temperature and a number signal to the backboard 10 via the gold finger.

For example, the first sensing module 21 includes a switch 211 and a sensor 212. The switch 211 includes six (first to sixth) terminals S1-S6. Each two of the six terminals cooperate to form a sub-switch, and each sub-switch can be switched by a button (not shown). For example, the first and the sixth terminals S1 and S6 cooperate to form a first sub-switch SW1; the second and the fifth terminals S2 and S5 cooperate to form a second sub-switch SW2, and the third and the fourth terminals S3 and S4 cooperate to form a third sub-switch SW3.

In the embodiment, the sensor 212 can be a TMP57 temperature sensor made by TEXAS INSTRUMENTS. The sensor 212 includes a power pin VCC, a data pin SDA, a clock pin SCL, a ground pin GND, and three address pins A0-A2. The power pin VCC is electronically connected to a power supply P5V. The data pin SDA and the clock pin SCL are electronically connected the power pins V33-1 and V33-2 of the gold finger J0 respectively. The ground pin GND is grounded. Each address pin is electronically connected to one terminal of a corresponding sub-switch via a pull-down resistor, and is electronically connected to the power supply P5V via a pull-up resistor.

The other terminal of each sub-switch is grounded. For example, the address pins A0-A2 are electronically connected to terminals S6, S5 and S4 of the sub-switches SW1-SW3 via pull-down resistors R4-R6 respectively, and are electronically connected to the power supply P5V via pull-up resistors R1-R3 respectively.

In the exemplary embodiment, the buttons of the switch 211 is operated to make all of the sub-switches SW1-SW3 to switch on. At this time, the address pins A0-A2 of the sensor 212 are grounded via the sub-switches SW1-SW3 respectively, and a voltage level of each address pin is low level (logic 0). Therefore, the sensor 212 generates a number signal “0,0,0” denoting the hard disk drive HDD0, and outputs the number signal “0,0,0” and the temperature of the hard disk drive HDD0 to the backboard 10 via the unused power pins V33-1 and V33-2.

The second to the eighth sending modules have the same circuit construction as a circuit construction of the first sending module 21. The switches of the second to eighth sensing modules are operated to make sensors of the second to eighth sensing modules to output number signals “0,0,1”, “0,1,0”, “0,1,1”, “1,0,0”, “1,0,1”, “1,1,0”, “1,1,1”, respectively. The number signals “0,0,1”, “0,1,0”, “0,1,1”, “1,0,0”, “1,0,1”, “1,1,0”, “1,1,1” corresponding to the hard disk drives HDD1-HDD7 respectively. The sensors of the second to eighth sensing modules output the number signals and temperatures of corresponding hard disk drive to the backboard 10 via the corresponding gold finger.

The fan group includes four fans. Each fan facing two of the hard disk drives, to dissipate heat generated by the two hard disk drives. For example, the fan group includes a first fan FAN1, a second fan FAN2, a third fan FAN3, and a fourth fan FAN4. The first fan FAN1 facing the hard disk drives HDD0 and HDD1. The second fan FAN2 facing the hard disk drives HDD2 and HDD3. The third fan FAN3 facing the hard disk drives HDD4 and HDD5. The fourth fan FAN4 facing the hard disk drives HDD6 and HDD7.

The controller 30 controls rotational speed of the fans FAN1-FAN4 according to the number signals and the temperatures detected by the sensors. In one embodiment, the controller 30 can be a baseboard management controller (BMC). The controller 30 includes a system management bus connector SMBus, and four pulse width modulation pin PWM1-PWM4. The system management bus connector SMBus is electronically connected to the backboard 10 via I2C bus, thereby connecting the controller 30 to the backboard 10, to allow the controller 30 to receive temperatures and number signals from the temperature sensing group 20. The pulse width modulation pins PWM1-PWM4 are electronically connected to the fans FAN1-FAN4 respectively.

In use, each sensor of the temperature sensing group 20 detects the temperature of corresponding hard disk drive, and outputs the temperature and the number signals to the controller 30 via the backboard 10 and the system management bus connector SMBus. The controller 30 finds a corresponding fan according to the number signal of each hard disk drive, and regulates the rotational speed of the corresponding fan according to the temperature of the hard disk drive. In the exemplary embodiment, the controller 30 compares the temperature of each hard disk drive to a predetermined temperature, the controller 30 increases the rotational speed of the corresponding fan when the temperature of one of the hard disk drive is higher than the predetermined temperature, and decreases the rotational speed of the corresponding fan after the temperature of one of the hard disk drive is lower than the predetermined temperature.

Thus, the rotational speed of the fans can be controlled by the controller 30 separately, according to the temperature of corresponding hard disk drive, which will reduce power use.

It is believed that the exemplary embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A temperature control device, comprising:
a temperature sensing group comprising a plurality of sensing modules, each sensing module detecting a temperature of a hard disk drive, numbering the hard disk drive, and outputting the temperature and a number signal corresponding to the hard disk drive;
a plurality of fans each facing and corresponding to one or more hard disk drives; and
a controller electronically connected to the plurality of sensing modules and the plurality of fans, the controller receiving the temperature and number signal from each sensing module, finding a corresponding fan according each number signal, and regulating a rotational speed of the corresponding fan according to the temperature of the hard disk drive.

2. The temperature control device of claim 1, wherein the controller compares the temperature of each hard disk drive to a predetermined temperature, the controller increases the rotational speed of the corresponding fan when the temperature of the hard disk drive is higher than the predetermined temperature, and decreases the rotational speed of the corresponding fan after the temperature of the hard disk drive is lower than the predetermined temperature.

3. The temperature control device of claim 1, wherein each sensing module comprises a switch and a sensor, each switch comprises a plurality of sub-switches, the sensor comprises a plurality of address pin corresponding to the plurality of sub-switches, each address pin is electronically connected to a power supply via a pull-up resistor, and is electronically connected to one terminal of the corresponding sub-switch via a pull-down resistor, the other terminal of the sub-switch is grounded; the sensing module numbers the hard disk drive by switching on one or more of the sub-switches.

4. The temperature control device of claim 1, wherein the controller is a baseboard management controller.

5. A server system, comprising:
a hard disk backboard;
a plurality of hard disk drives electronically connected to the hard disk backboard;
a temperature sensing group comprising a plurality of sensing modules, each sensing module detecting a temperature of one of the plurality of hard disk drives, numbering the hard disk drive, and outputting the temperature and a number signal corresponding to the hard disk drive;
a plurality of fans each facing and corresponding to one or more of the plurality of hard disk drives; and
a controller electronically connected to the plurality of sensing modules and the plurality of fans, the controller receiving the temperature and number signal from each sensing module, finding a corresponding fan according each number signal, and regulating a rotational speed of the corresponding fan according to the temperature of the hard disk drive.

6. The server system of claim 5, wherein the controller compares the temperature of each hard disk drive to a predetermined temperature, the controller increases the rotational speed of the corresponding fan when the temperature of the hard disk drive is higher than the predetermined temperature, and decreases the rotational speed of the corresponding fan after the temperature of the hard disk drive is lower than the predetermined temperature.

7. The server system of claim 5, wherein each sensing module comprises a switch and a sensor, each switch comprises a plurality of sub-switches, the sensor comprises a plurality of address pin corresponding to the plurality of sub-switches, each address pin is electronically connected to a power supply via a pull-up resistor, and is electronically connected to one terminal of the corresponding sub-switch via a pull-down resistor, the other terminal of the sub-switch is grounded; the sensing module numbers the hard disk drive by switching on one or more of the sub-switches.

8. The server system of claim 7, wherein each sensor comprises a data pin and a clock pin, each hard disk drive comprises a gold finger connecting the hard disk drive to the backboard, the gold finger comprises two unused power pins electronically connected to the data pin and the clock pin respectively.

9. The server system of claim 8, wherein the controller comprises a system management bus connector electronically connected to the backboard.

10. The server system of claim 5, wherein the controller is a baseboard management controller.
